(19) United States
(12) Patent Application Publication
(10) Pub. No.: US 2020/0135554 A1
(43) Pub. Date: Apr. 30, 2020

(54) Water Vapor Based Fluorine Containing Plasma For Removal Of Hardmask

(71) Applicants: Mattson Technology, Inc., Fremont, CA (US); Beijing E-Town Semiconductor Technology, Co., LTD, Beijing (CN)

(72) Inventors: Li Hou, Cupertino, CA (US); Vijay M. Vaniapura, Tracy, CA (US); Jeyta Anand Sahay, Livermore, CA (US); Hua Chung, Saratoga, CA (US); Shuang Meng, Milpitas, CA (US); Shawming Ma, Sunnyvale, CA (US)

(21) Appl. No.: 16/598,423

(22) Filed: Oct. 10, 2019

Related U.S. Application Data
(60) Provisional application No. 62/872,873, filed on Jul. 11, 2019.
(60) Provisional application No. 62/818,260, filed on Mar. 14, 2019.
(60) Provisional application No. 62/776,116, filed on Dec. 6, 2018.
(60) Provisional application No. 62/750,908, filed on Oct. 26, 2018.

(51) Int. Cl. H01L 21/768; H01L 21/02; H01L 21/3213; H01J 37/32

(52) U.S. Cl. CPC H01L 21/76865; H01L 21/02274; H01J 37/32788; H01J 37/32724; H01L 21/32136

(57) ABSTRACT

Apparatus, systems, and methods for conducting a hardmask (e.g., boron doped amorphous carbon hardmask) removal process on a workpiece are provided. In one example implementation, a method includes supporting a workpiece on a workpiece support in a processing chamber. The method can include generating a plasma from a process gas in a plasma chamber using a plasma source. The plasma chamber can be separated from the processing chamber by a separation grid. The method can include exposing the workpiece to one or more radicals generated in the plasma to perform a plasma strip process on the workpiece to at least partially remove the hardmask layer from the workpiece. The method can include exposing the workpiece to water vapor as a passivation agent during the plasma strip process.

### PRIORITY CLAIM

The present application claims the benefit of priority of U.S. Provisional Application Ser. No. 62/750,908, filed on Oct. 26, 2018, titled “Water Vapor Based Fluorine Containing Plasma for Removal of Hardmask,” which is incorporated herein by reference.

The present application claims the benefit of priority of U.S. Provisional Application Ser. No. 62/776,116, filed on Dec. 6, 2018, titled “Water Vapor Based Fluorine Containing Plasma for Removal of Hardmask,” which is incorporated herein by reference.

The present application claims the benefit of priority of U.S. Provisional Application Ser. No. 62/818,260, filed on Mar. 14, 2019, titled “Water Vapor Based Fluorine Containing Plasma for Removal of Hardmask,” which is incorporated herein by reference.

The present application claims the benefit of priority of U.S. Provisional Application Ser. No. 62/872,873, filed on Jul. 11, 2019, titled “Water Vapor Based Fluorine Containing Plasma for Removal of Hardmask,” which is incorporated herein by reference.

### FIELD

The present disclosure relates generally to processing semiconductor workpieces.

### BACKGROUND

Plasma strip processes (e.g., dry strip processes) can be used in semiconductor fabrication as a method for removing hardmask and/or other materials patterned on a workpiece. Plasma strip processes can use reactive species (e.g., radicals) extracted from a plasma generated from one or more process gases to etch and/or remove photoresist and other mask layers from a surface of a workpiece. For instance, in some plasma strip processes, neutral species from a plasma generated in a remote plasma chamber pass through a separation grid into a processing chamber. The neutral species can be exposed to a workpiece, such as a semiconductor wafer, to remove hardmask from the surface of the workpiece.

### SUMMARY

Aspects and advantages of embodiments of the present disclosure will be set forth in part in the following description, or may be learned from the description, or may be learned through practice of the embodiments.

In one example implementation, a method includes supporting a workpiece on a workpiece support in a processing chamber. The method can include generating a plasma from a process gas in a plasma chamber using a plasma source. The plasma chamber can be separated from the processing chamber by a separation grid. The method can include exposing the workpiece to one or more radicals generated in the plasma to perform a plasma strip process on the workpiece to at least partially remove the hardmask layer from the workpiece. The method can include exposing the workpiece to water vapor as a passivation agent during the plasma strip process.

Other example aspects of the present disclosure are directed to systems, methods, and apparatus for processing of workpieces.

These and other features, aspects and advantages of various embodiments will become better understood with reference to the following description and appended claims. The accompanying drawings, which are incorporated in and constitute a part of this specification, illustrate embodiments of the present disclosure and, together with the description, serve to explain the related principles.

### BRIEF DESCRIPTION OF THE DRAWINGS

Detailed discussion of embodiments directed to one of ordinary skill in the art are set forth in the specification, which makes reference to the appended figures, in which:

FIG. 1 depicts an example hardmask removal process on a high aspect ratio structure;

FIG. 2 depicts an example hardmask removal process on a high aspect ratio structure according to example embodiments of the present disclosure;

FIG. 3 depicts an example plasma processing apparatus according to example embodiments of the present disclosure;

FIG. 4 depicts a flow diagram of an example method according to example embodiments of the present disclosure;

FIG. 5 depicts an example plasma processing apparatus according to example embodiments of the present disclosure;

FIG. 6 depicts example injection of water vapor at a separation grid according to example embodiments of the present disclosure;

FIG. 7 depicts an example plasma processing apparatus according to example embodiments of the present disclosure;

FIG. 8 depicts an example plasma processing apparatus according to example embodiments of the present disclosure;

FIG. 9 depicts an example hardmask removal process on a high aspect ratio structure; and

FIG. 10 depicts an example hardmask removal process on a high aspect ratio structure according to example embodiments of the present disclosure.

### DETAILED DESCRIPTION

Reference now will be made in detail to embodiments, one or more examples of which are illustrated in the drawings. Each example is provided by way of explanation of the embodiments, not limitation of the present disclosure. In fact, it will be apparent to those skilled in the art that various modifications and variations can be made to the embodiments without departing from the scope or spirit of the present disclosure. For instance, features illustrated or described as part of one embodiment can be used with another embodiment to yield a still further embodiment. Thus, it is intended that aspects of the present disclosure cover such modifications and variations.

Example aspects of the present disclosure are directed to processes for removing a hardmask layer (e.g., boron doped amorphous carbon hardmask) from a workpiece in semiconductor processing. Various materials such as boron or metal doped amorphous carbon can be used as a hardmask layer in high aspect ratio dielectric etch applications to produce advanced semiconductor devices. Plasma strip processes can be used to remove remaining hardmask after conducting etch processes. As device features continuously shrink, very high selectivity of hardmask relative to silicon dioxide and silicon nitride layers can be required for post etch hardmask removal.

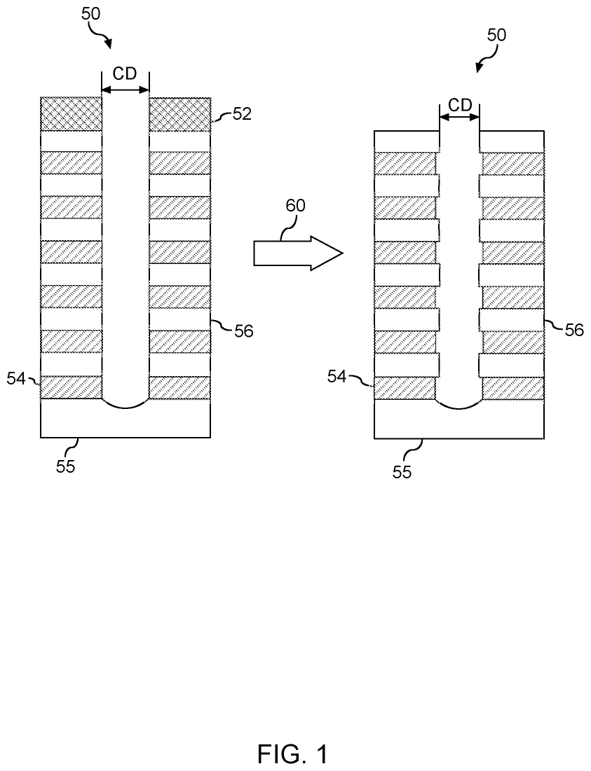

Inadequate selectivity of the hardmask relative to silicon dioxide and silicon nitride in plasma strip processes can pose challenges in workpiece processing, such as hardmask removal from high aspect ratio structures in semiconductor processing. For example, FIG. 1 depicts an example hardmask removal process for a high aspect ratio structure 50. The high aspect ratio structure 50 includes a plurality of silicon nitride layers 54 and silicon dioxide layers 56 disposed on a substrate 55, such as a silicon substrate. The high aspect ratio structure 50 is associated with a critical dimension CD. A hardmask 52 can remain on the high aspect ratio structure 50 after an etch process.

A plasma strip process 60 can be conducted on the high aspect ratio structure 50 to remove the hardmask 52. The plasma strip process can expose the hardmask 52 to one or more species generated in a plasma chamber to remove the hardmask 52. As shown in FIG. 1, if selectivity of the plasma strip process for the hardmask 52 is poor relative to silicon nitride and silicon dioxide, the high aspect ratio structure 50 can result in a saw-toothed sidewall, negatively affecting the critical dimension CD requirements.

Example aspects of the present disclosure are directed to a plasma strip process with improved selectivity and faster ash rate for removal of a hardmask layer, such as removal of a hardmask layer from a high aspect ratio structure having one or more silicon nitride layers and one or more silicon dioxide layers. In some embodiments, water vapor can be used in conjunction with a fluorine containing chemistry as a process gas during the plasma strip process. The water molecules can act as passivating agents to reduce silicon dioxide and silicon nitride removal during the strip process.

The water vapor can be exposed to the workpiece in various ways without deviating from the scope of the present disclosure. For instance, in some embodiments, the water vapor can be introduced as a part of the process gas and/or in conjunction with the process gas. The process gas can include a fluorine containing gas and other gases (e.g., oxygen gas, hydrogen gas, dilution gas, etc.). A plasma source (e.g., inductive plasma source) can induce a plasma in the process gas. As another example, the water vapor can be delivered post plasma to a processing chamber below a separation grid separating a plasma chamber from the processing chamber. As yet another example, the water vapor can be introduced post plasma at the separation grid, such as between grid plates of the separation grid.

In this way, the hardmask removal processes according to example aspects of the present disclosure can provide a number of technical effects and benefits. For example, the hardmask removal processes according to example aspects of the present disclosure can provide for improved selectivity of the hardmask layer relative to silicon dioxide layers and silicon nitride layers in a workpiece. As another example, the hardmask removal processes according to example aspects of the present disclosure can provide a high ash rate, such as greater than about 1500 Angstroms per minute.

Aspects of the present disclosure are discussed with reference to a “workpiece” “wafer” or semiconductor wafer for purposes of illustration and discussion. Those of ordinary skill in the art, using the disclosures provided herein, will understand that the example aspects of the present disclosure can be used in association with any semiconductor substrate or other suitable substrate. In addition, the use of the term “about” in conjunction with a numerical value is intended to refer to within twenty percent (20%) of the stated numerical value. A “pedestal” refers to any structure that can be used to support a workpiece.

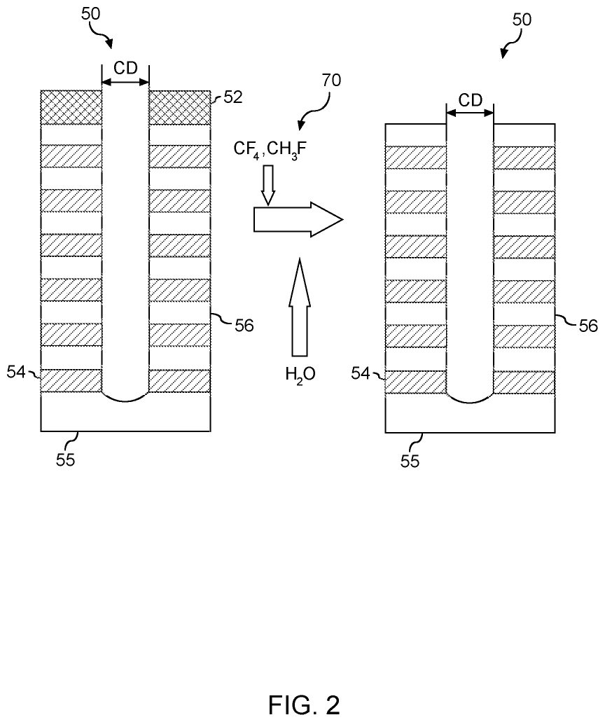

FIG. 2 depicts an overview of an example hardmask removal process 70 for a workpiece having a high aspect ratio structure 50 according to example embodiments of the present disclosure. The high aspect ratio structure 50 includes a plurality of silicon nitride layers 54 and a plurality of silicon dioxide layers 56 disposed on a substrate 55, such as a silicon substrate. The high aspect ratio structure 50 is associated with a critical dimension CD. A hardmask 52 can remain on the high aspect ratio structure 50 after an etch process.

A plasma strip process 70 according to example aspects of the present disclosure can be conducted on the high aspect ratio structure 50 to remove the hardmask 52. The plasma strip process 70 can expose the hardmask 52 to one or more species generated in a plasma chamber from a fluorine containing gas (e.g., CF₄, CH₂F₂, CH₃F) to remove the hardmask 52. The plasma strip process 70 can expose the workpiece to water vapor as a passivation agent for the silicon nitride and silicon dioxide layers.

Passivation of the silicon nitride and silicon dioxide layers leads to improved selectivity of the plasma strip process 70 for a hardmask layer (e.g., boron doped amorphous hardmask layer) relative to the silicon nitride and silicon dioxide layers. Because of the improved selectivity of the plasma strip process 70, the high aspect ratio structure 50 can result in a smooth sidewall, leading to improved critical dimension (CD) control.

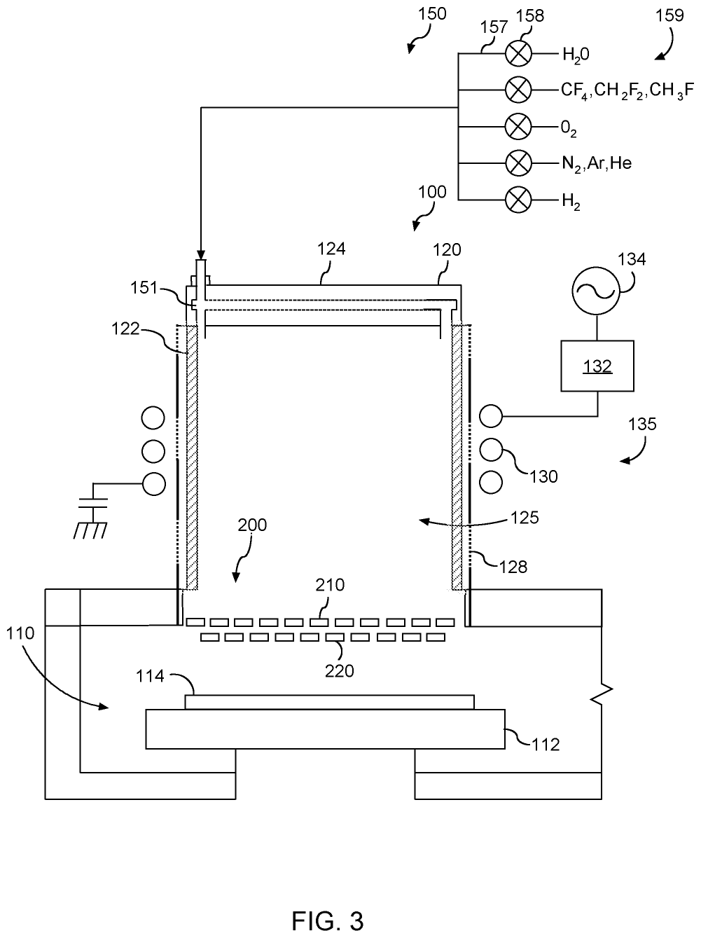

FIG. 3 depicts an example plasma processing apparatus 100 that can be used to perform hardmask removal processes according to example embodiments of the present disclosure. As illustrated, plasma processing apparatus 100 includes a processing chamber 110 and a plasma chamber 120 that is separated from the processing chamber 110. Processing chamber 110 includes a workpiece support or pedestal 112 operable to hold a workpiece 114 to be processed, such as a semiconductor wafer. In this example illustration, a plasma is generated in plasma chamber 120 (i.e., plasma generation region) by an inductively coupled plasma source 135 and desired species are channeled from the plasma chamber 120 to the surface of workpiece 114 through a separation grid assembly 200.

Aspects of the present disclosure are discussed with reference to an inductively coupled plasma source for purposes of illustration and discussion. Those of ordinary skill in the art, using the disclosures provided herein, will understand that any plasma source (e.g., inductively coupled plasma source, capacitively coupled plasma source, etc.) can be used without deviating from the scope of the present disclosure.

The plasma chamber 120 includes a dielectric side wall 122 and a ceiling 124. The dielectric side wall 122, ceiling 124, and separation grid 200 define a plasma chamber interior 125. Dielectric side wall 122 can be formed from a dielectric material, such as quartz and/or alumina. The inductively coupled plasma source 135 can include an induction coil 130 disposed adjacent the dielectric side wall 122 about the plasma chamber 120. The induction coil 130 is coupled to an RF power generator 134 through a suitable matching network 132. Process gases (e.g., as described in detail below) can be provided to the chamber interior from gas supply 150 and annular gas distribution channel 151 or other suitable gas introduction mechanism. When the induction coil 130 is energized with RF power from the RF power generator 134, a plasma can be generated in the plasma chamber 120. In a particular embodiment, the plasma processing apparatus 100 can include an optional grounded Faraday shield 128 to reduce capacitive coupling of the induction coil 130 to the plasma.

As shown in FIG. 3, a separation grid 200 separates the plasma chamber 120 from the processing chamber 110. The separation grid 200 can be used to perform ion filtering from a mixture generated by plasma in the plasma chamber 120 to generate a filtered mixture. The filtered mixture can be exposed to the workpiece 114 in the processing chamber.

In some embodiments, the separation grid 200 can be a multi-plate separation grid. For instance, the separation grid 200 can include a first grid plate 210 and a second grid plate 220 that are spaced apart in parallel relationship to one another. The first grid plate 210 and the second grid plate 220 can be separated by a distance.

The first grid plate 210 can have a first grid pattern having a plurality of holes. The second grid plate 220 can have a second grid pattern having a plurality of holes. The first grid pattern can be the same as or different from the second grid pattern. Charged particles can recombine on the walls in their path through the holes of each grid plate 210, 220 in the separation grid. Neutral species (e.g., radicals) can flow relatively freely through the holes in the first grid plate 210 and the second grid plate 220. The size of the holes and thickness of each grid plate 210 and 220 can affect transparency for both charged and neutral particles.

In some embodiments, the first grid plate 210 can be made of metal (e.g., aluminum) or other electrically conductive material and/or the second grid plate 220 can be made from either an electrically conductive material or dielectric material (e.g., quartz, ceramic, etc.). In some embodiments, the first grid plate 210 and/or the second grid plate 220 can be made of other materials, such as silicon or silicon carbide. In the event a grid plate is made of metal or other electrically conductive material, the grid plate can be grounded. In some embodiments, the grid assembly can include a single grid with a single grid plate.

As shown in FIG. 3, the apparatus 100 can include a gas delivery system 150 configured to deliver process gas to the plasma chamber 120, for instance, via gas distribution channel 151 or other distribution system (e.g., showerhead). The gas delivery system can include a plurality of feed gas lines 159. The feed gas lines 159 can be controlled using valves and/or mass flow controllers to deliver a desired amount of gases into the plasma chamber as process gas. As shown in FIG. 3, the gas delivery system 150 can include feed gas line(s) for delivery of a fluorine containing gas (e.g., CF₄, CH₂F₂, CH₃F). The gas delivery system 150 can include feed gas line(s) for delivery of an oxygen gas (e.g., O₂). The gas delivery system 150 can include feed gas line(s) for delivery of a dilution gas (e.g., N₂, Ar, He, or other inert gas). The gas delivery system 150 can include feed gas line(s) for delivery of a hydrogen gas (e.g., H₂).

According to example aspects of the present disclosure, the apparatus 100 can include a feed gas line 157 for delivery of water vapor (H₂O) to the plasma chamber 120 as part of the process gas. A control valve and/or mass flow controller 158 can be used to control the flow rate of the water vapor as part of the process gas into the plasma chamber 120. The water vapor can be used as a passivation agent for the silicon dioxide layers, silicon nitride layers, and other layers on the workpiece during a plasma strip process.

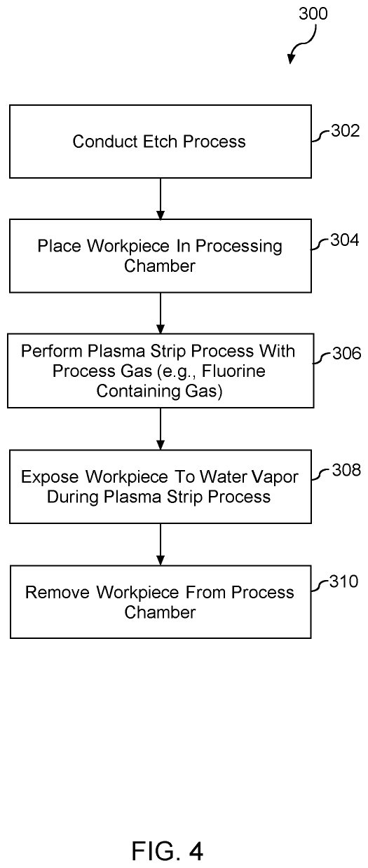

FIG. 4 depicts a flow diagram of one example method (300) according to example aspects of the present disclosure. The method (300) will be discussed with reference to the plasma processing apparatus 100 of FIG. 3 by way of example. The method (300) can be implemented in any suitable plasma processing apparatus. FIG. 4 depicts steps performed in a particular order for purposes of illustration and discussion. Those of ordinary skill in the art, using the disclosures provided herein, will understand that various steps of any of the methods described herein can be omitted, expanded, performed simultaneously, rearranged, and/or modified in various ways without deviating from the scope of the present disclosure. In addition, various steps (not illustrated) can be performed without deviating from the scope of the present disclosure.

At (302), the method can include conducting an etch process to etch a layer on a workpiece. The etch process can be carried out in a separate processing apparatus relative to the remainder of method (300) or can be conducted using the same processing apparatus. The etch process can remove at least a portion of a layer on the workpiece.

At (304), the method can include placing a workpiece in a processing chamber of a plasma processing apparatus. The processing chamber can be separated from a plasma chamber (e.g., separated by a separation grid assembly). For instance, the method can include placing a workpiece 114 onto workpiece support 112 in the processing chamber 110 of FIG. 3.

At (306), the method can include performing a plasma strip process, for instance, to remove a hardmask layer from the workpiece. The plasma strip process can include, for instance, generating a plasma from a process gas in the plasma chamber 120, filtering ions with the separation grid assembly 200, and allowing neutral radicals to pass through the separation grid assembly 200. The neutral radicals can be exposed to the workpiece 114 to at least partially remove hardmask from the workpiece.

The process gas used during the plasma strip process at (306) can include a fluorine containing gas. For instance, the process gas can include CF₄. As another example, the process gas can include CH₂F₂. As another example, the process gas can include CH₃F. Other fluorine containing gases can be used without deviating from the scope of the present disclosure.

Other suitable gases can be included in the process gas. For instance, the process gas can include an O₂ gas. The process gas can include an H₂ gas. The process gas can include a dilution gas, such as nitrogen gas N₂ and/or an inert gas, such as He, Ar or other inert gas.

At (308), the method can include exposing the workpiece to water vapor as a passivation agent. The water vapor can improve selectivity of the strip processes for the hardmask layer relative to the silicon nitride layers and silicon dioxide layers. The water vapor can be introduced as part of and/or in conjunction with the process gas. For instance, feed gas line 157 can introduce the feed gas to the plasma chamber 120. Other suitable methods for introducing the water vapor as a passivation agent will be discussed in detail below.

At (310) of FIG. 4, the method can include removing the workpiece from the processing chamber. For instance, the workpiece 114 can be removed from workpiece support 112 in the processing chamber 110. The plasma processing apparatus can then be conditioned for future processing of additional workpieces.

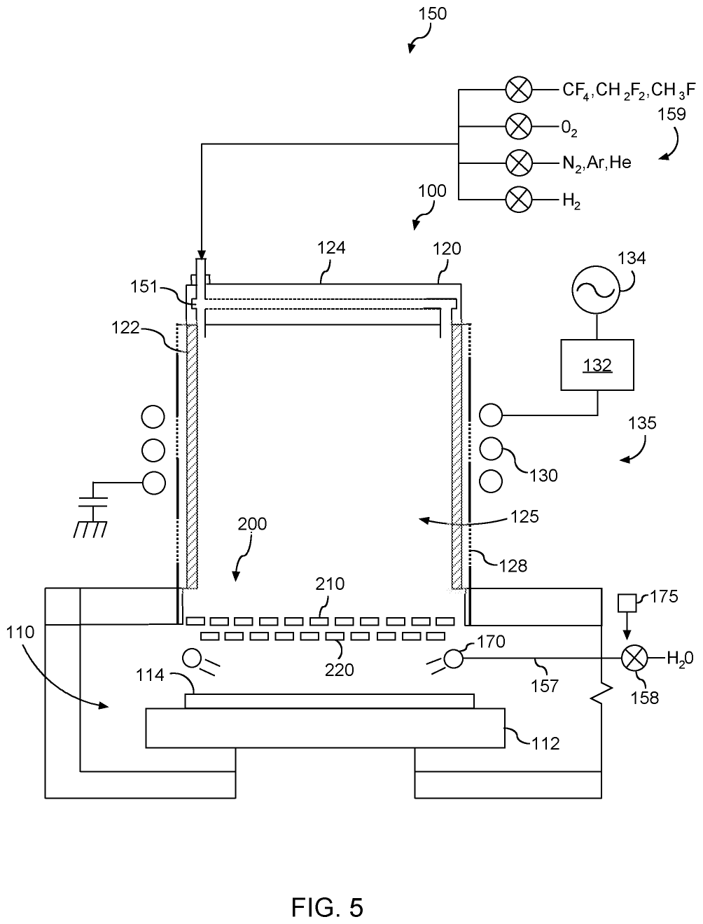

Other suitable methods for introducing water vapor as a passivation agent can be used without deviating from the scope of the present disclosure. For instance, FIG. 5 depicts a plasma processing apparatus 100 similar to that of FIG. 3. However, the apparatus 100 of FIG. 5 includes a water vapor feed line 157 arranged to deliver water vapor into the processing chamber 110. More particularly, the water vapor feed line 157 can be coupled to water vapor distribution port 170 arranged to provide water vapor at a location below the separation grid 200, such as at a location between the separation grid 200 and the workpiece 114. The control valve and/or mass flow controller 158 can control the flow rate of the water vapor into the processing chamber. A temperature regulation system (e.g., one or more heat sources) can be used to regulate the temperature of one or more portions or all of the feed line 157 to reduce condensation resulting from the water vapor.

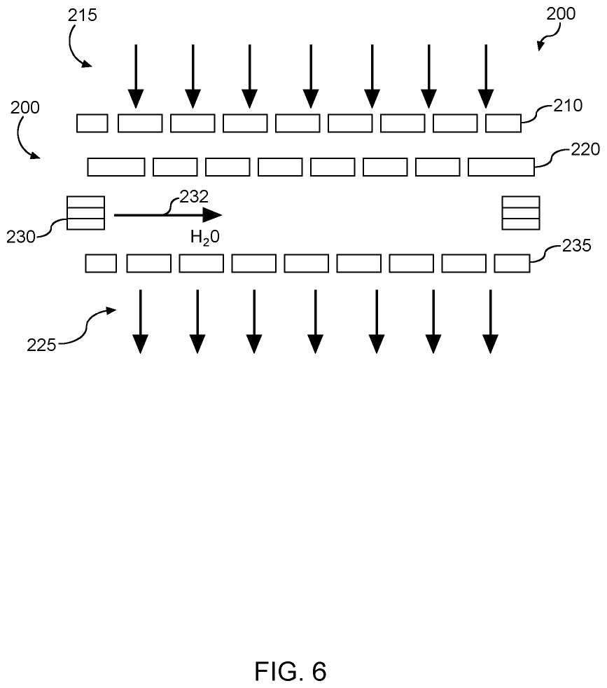

FIG. 6 depicts example introduction of water vapor into a plasma processing apparatus according to example embodiments of the present disclosure. As shown, FIG. 6 depicts an example separation grid 200 for injection of water vapor post plasma according to example embodiments of the present disclosure. The separation grid 200 includes a first grid plate 210 and a second grid plate 220 disposed in parallel relationship. The first grid plate 210 and the second grid plate 220 can provide for ion/UV filtering.

The first grid plate 210 can have a first grid pattern having a plurality of holes. The second grid plate 220 can have a second grid pattern having a plurality of holes. The first grid pattern can be the same as or different from the second grid pattern. Species 215 from the plasma can be exposed to the separation grid 200. Charged particles (e.g., ions) can recombine on the walls in their path through the holes of each grid plate 210, 220 in the separation grid 200. Neutral species can flow relatively freely through the holes in the first grid plate 210 and the second grid plate 220.

Subsequent to the second grid plate 220, a water vapor injection source 230 can be configured to introduce water vapor 232 into the species passing through the separation grid 200. A mixture 225 including water molecules resulting from the injection of water vapor can pass through a third grid plate 235 for exposure to the workpiece in the processing chamber.

The present example is discussed with reference to a separation grid with three grid plates for example purposes. Those of ordinary skill in the art, using the disclosures provided herein, will understand that more or fewer grid plates can be used without deviating from the scope of the present disclosure. In addition, the water vapor can be mixed with the species at any point in the separation grid and/or after the separation grid in the processing chamber. For instance, the water vapor injection source 230 can be located between first grid plate 210 and second grid plate 220.

The plasma strip processes according to example aspects of the present disclosure can be implemented using other plasma processing apparatus without deviating from the scope of the present disclosure.

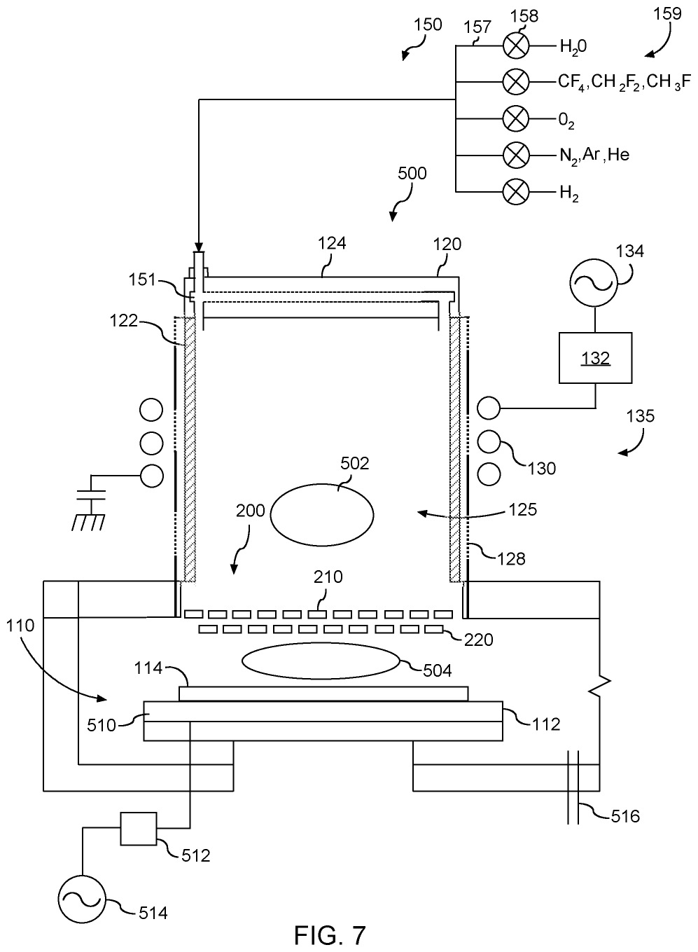

FIG. 7 depicts an example plasma processing apparatus 500 that can be used to implement processes according to example embodiments of the present disclosure. The plasma processing apparatus 500 is similar to the plasma processing apparatus 100 of FIG. 3.

More particularly, plasma processing apparatus 500 includes a processing chamber 110 and a plasma chamber 120 that is separated from the processing chamber 110. Processing chamber 110 includes a substrate holder or pedestal 112 operable to hold a workpiece 114 to be processed, such as a semiconductor wafer. In this example illustration, a plasma is generated in plasma chamber 120 (i.e., plasma generation region) by an inductively coupled plasma source 135 and desired species are channeled from the plasma chamber 120 to the surface of substrate 114 through a separation grid assembly 200.

The plasma chamber 120 includes a dielectric side wall 122 and a ceiling 124. The dielectric side wall 122, ceiling 124, and separation grid 200 define a plasma chamber interior 125. Dielectric side wall 122 can be formed from a dielectric material, such as quartz and/or alumina. The inductively coupled plasma source 135 can include an induction coil 130 disposed adjacent the dielectric side wall 122 about the plasma chamber 120. The induction coil 130 is coupled to an RF power generator 134 through a suitable matching network 132. Process gases (e.g., an inert gas) can be provided to the chamber interior from gas supply 150 and annular gas distribution channel 151 or other suitable gas introduction mechanism. When the induction coil 130 is energized with RF power from the RF power generator 134, a plasma can be generated in the plasma chamber 120. In a particular embodiment, the plasma processing apparatus 100 can include an optional grounded Faraday shield 128 to reduce capacitive coupling of the induction coil 130 to the plasma.

As shown in FIG. 7, a separation grid 200 separates the plasma chamber 120 from the processing chamber 110. The separation grid 200 can be used to perform ion filtering from a mixture generated by plasma in the plasma chamber 120 to generate a filtered mixture. The filtered mixture can be exposed to the workpiece 114 in the processing chamber.

In some embodiments, the separation grid 200 can be a multi-plate separation grid. For instance, the separation grid 200 can include a first grid plate 210 and a second grid plate 220 that are spaced apart in parallel relationship to one another. The first grid plate 210 and the second grid plate 220 can be separated by a distance.

The first grid plate 210 can have a first grid pattern having a plurality of holes. The second grid plate 220 can have a second grid pattern having a plurality of holes. The first grid pattern can be the same as or different from the second grid pattern. Charged particles can recombine on the walls in their path through the holes of each grid plate 210, 220 in the separation grid. Neutral species (e.g., radicals) can flow relatively freely through the holes in the first grid plate 210 and the second grid plate 220. The size of the holes and thickness of each grid plate 210 and 220 can affect transparency for both charged and neutral particles.

In some embodiments, the first grid plate 210 can be made of metal (e.g., aluminum) or other electrically conductive material and/or the second grid plate 220 can be made from either an electrically conductive material or dielectric material (e.g., quartz, ceramic, etc.). In some embodiments, the first grid plate 210 and/or the second grid plate 220 can be made of other materials, such as silicon or silicon carbide. In the event a grid plate is made of metal or other electrically conductive material, the grid plate can be grounded.

The example plasma processing apparatus 500 of FIG. 7 is operable to generate a first plasma 502 (e.g., a remote plasma) in the plasma chamber 120 and a second plasma 504 (e.g., a direct plasma) in the processing chamber 110. As used herein, a “remote plasma” refers to a plasma generated remotely from a workpiece, such as in a plasma chamber separated from a workpiece by a separation grid. As used herein, a “direct plasma” refers to a plasma that is directly exposed to a workpiece, such as a plasma generated in a processing chamber having a pedestal operable to support the workpiece.

More particularly, the plasma processing apparatus 500 of FIG. 7 includes a bias source having bias electrode 510 in the pedestal 112. The bias electrode 510 can be coupled to an RF power generator 514 via a suitable matching network 512. When the bias electrode 510 is energized with RF energy, a second plasma 504 can be generated from a mixture in the processing chamber 110 for direct exposure to the workpiece 114. The processing chamber 110 can include a gas exhaust port 516 for evacuating a gas from the processing chamber 110.

As shown in FIG. 7, the apparatus 100 can include a gas delivery system 150 configured to deliver process gas to the plasma chamber 120, for instance, via gas distribution channel 151 or other distribution system (e.g., showerhead). The gas delivery system can include a plurality of feed gas lines 159. The process gas can be delivered to the processing chamber 110 via the separation grid 200 acting as a showerhead.

The feed gas lines 159 can be controlled using valves and/or mass flow controllers to deliver a desired amount of gases into the plasma chamber as process gas. As shown in FIG. 7, the gas delivery system 150 can include feed gas line(s) for delivery of a fluorine containing gas (e.g., CF₄, CH₂F₂, CH₃F). The gas delivery system 150 can include feed gas line(s) for delivery of an oxygen gas (e.g., O₂). The gas delivery system 150 can include feed gas line(s) for delivery of a dilution gas (e.g., N₂, Ar, He, or other inert gas). The gas delivery system 150 can include feed gas line(s) for delivery of a hydrogen gas (e.g., H₂).

According to example aspects of the present disclosure, the apparatus 500 can include a feed gas line 157 for delivery of water vapor (H₂O) to the plasma chamber 120 as part of the process gas. A control valve and/or mass flow controller 158 can be used to control the flow rate of the water vapor as part of the process gas into the plasma chamber 120. The water vapor can be used as a passivation agent for the silicon dioxide layers, silicon nitride layers, and other layers on the workpiece during a plasma strip process.

The water vapor can be introduced as a passivation agent in the apparatus 500 of FIG. 6 in other ways without deviating from the scope of the present disclosure. For instance, the water vapor can be introduced at a location in the processing chamber, such as at a location below the separation grid 200. As another example, the water vapor can be introduced between grid plates 210 and 220 of the separation grid.

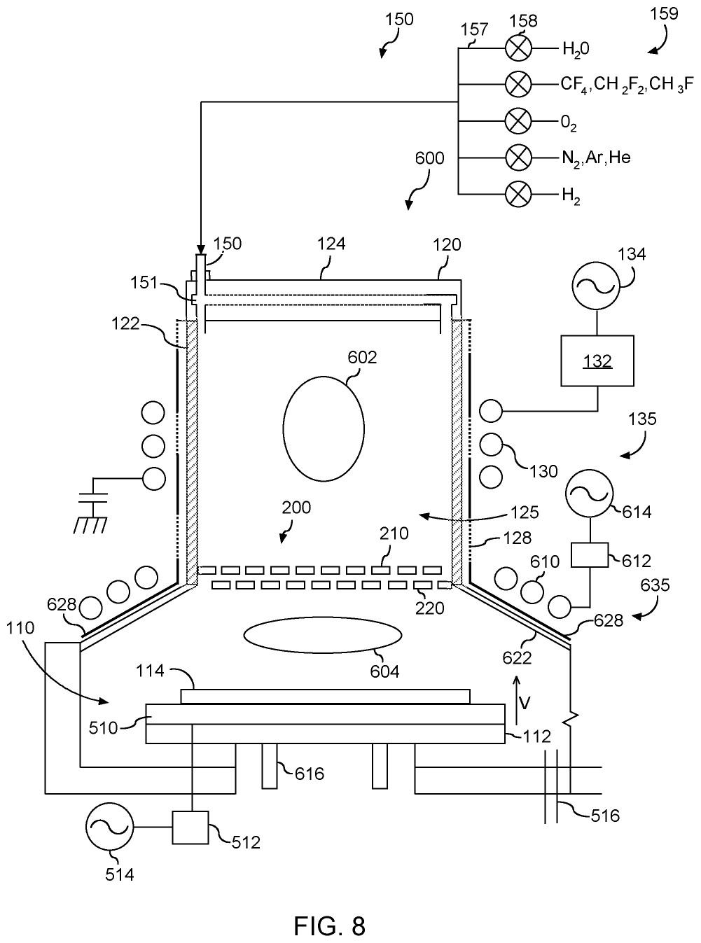

FIG. 8 depicts a processing chamber 600 similar to that of FIG. 3 and FIG. 7. More particularly, plasma processing apparatus 600 includes a processing chamber 110 and a plasma chamber 120 that is separated from the processing chamber 110. Processing chamber 110 includes a substrate holder or pedestal 112 operable to hold a workpiece 114 to be processed, such as a semiconductor wafer. In this example illustration, a plasma is generated in plasma chamber 120 (i.e., plasma generation region) by an inductively coupled plasma source 135 and desired species are channeled from the plasma chamber 120 to the surface of substrate 114 through a separation grid assembly 200.

The plasma chamber 120 includes a dielectric side wall 122 and a ceiling 124. The dielectric side wall 122, ceiling 124, and separation grid 200 define a plasma chamber interior 125. Dielectric side wall 122 can be formed from a dielectric material, such as quartz and/or alumina. The inductively coupled plasma source 135 can include an induction coil 130 disposed adjacent the dielectric side wall 122 about the plasma chamber 120. The induction coil 130 is coupled to an RF power generator 134 through a suitable matching network 132. Process gas (e.g., an inert gas) can be provided to the chamber interior from gas supply 150 and annular gas distribution channel 151 or other suitable gas introduction mechanism. When the induction coil 130 is energized with RF power from the RF power generator 134, a plasma can be generated in the plasma chamber 120. In a particular embodiment, the plasma processing apparatus 100 can include an optional grounded Faraday shield 128 to reduce capacitive coupling of the induction coil 130 to the plasma.

As shown in FIG. 8, a separation grid 200 separates the plasma chamber 120 from the processing chamber 110. The separation grid 200 can be used to perform ion filtering from a mixture generated by plasma in the plasma chamber 120 to generate a filtered mixture. The filtered mixture can be exposed to the workpiece 114 in the processing chamber.

In some embodiments, the separation grid 200 can be a multi-plate separation grid. For instance, the separation grid 200 can include a first grid plate 210 and a second grid plate 220 that are spaced apart in parallel relationship to one another. The first grid plate 210 and the second grid plate 220 can be separated by a distance.

The first grid plate 210 can have a first grid pattern having a plurality of holes. The second grid plate 220 can have a second grid pattern having a plurality of holes. The first grid pattern can be the same as or different from the second grid pattern. Charged particles can recombine on the walls in their path through the holes of each grid plate 210, 220 in the separation grid. Neutral species (e.g., radicals) can flow relatively freely through the holes in the first grid plate 210 and the second grid plate 220. The size of the holes and thickness of each grid plate 210 and 220 can affect transparency for both charged and neutral particles.

In some embodiments, the first grid plate 210 can be made of metal (e.g., aluminum) or other electrically conductive material and/or the second grid plate 220 can be made from either an electrically conductive material or dielectric material (e.g., quartz, ceramic, etc.). In some embodiments, the first grid plate 210 and/or the second grid plate 220 can be made of other materials, such as silicon or silicon carbide. In the event a grid plate is made of metal or other electrically conductive material, the grid plate can be grounded.

The example plasma processing apparatus 600 of FIG. 8 is operable to generate a first plasma 602 (e.g., a remote plasma) in the plasma chamber 120 and a second plasma 604 (e.g., a direct plasma) in the processing chamber 110. As shown, the plasma processing apparatus 600 can include an angled dielectric sidewall 622 that extends from the vertical sidewall 122 associated with the remote plasma chamber 120. The angled dielectric sidewall 622 can form a part of the processing chamber 110.

A second inductive plasma source 635 can be located proximate the dielectric sidewall 622. The second inductive plasma source 635 can include an induction coil 610 coupled to an RF generator 614 via a suitable matching network 612. The induction coil 610, when energized with RF energy, can induce a direct plasma 604 from a mixture in the processing chamber 110. A Faraday shield 628 can be disposed between the induction coil 610 and the sidewall 622.

The pedestal 112 can be movable in a vertical direction V. For instance, the pedestal 112 can include a vertical lift 616 that can be configured to adjust a distance between the pedestal 112 and the separation grid assembly 200. As one example, the pedestal 112 can be located in a first vertical position for processing using the remote plasma 602. The pedestal 112 can be in a second vertical position for processing using the direct plasma 604. The first vertical position can be closer to the separation grid assembly 200 relative to the second vertical position.

The plasma processing apparatus 600 of FIG. 8 includes a bias source having bias electrode 510 in the pedestal 112. The bias electrode 510 can be coupled to an RF power generator 514 via a suitable matching network 512. The processing chamber 110 can include a gas exhaust port 516 for evacuating a gas from the processing chamber 110.

As shown in FIG. 8, the apparatus 100 can include a gas delivery system 150 configured to deliver process gas to the plasma chamber 120, for instance, via gas distribution channel 151 or other distribution system (e.g., showerhead). The gas delivery system can include a plurality of feed gas lines 159. The process gas can be delivered to the processing chamber 110 via the separation grid 200 acting as a showerhead.

The feed gas lines 159 can be controlled using valves and/or mass flow controllers to deliver a desired amount of gases into the plasma chamber as process gas. As shown in FIG. 8, the gas delivery system 150 can include feed gas line(s) for delivery of a fluorine containing gas (e.g., CF₄, CH₂F₂, CH₃F). The gas delivery system 150 can include feed gas line(s) for delivery of an oxygen gas (e.g., O₂). The gas delivery system 150 can include feed gas line(s) for delivery of a dilution gas (e.g., N₂, Ar, He, or other inert gas). The gas delivery system 150 can include feed gas line(s) for delivery of a hydrogen gas (e.g., H₂).

According to example aspects of the present disclosure, the apparatus 600 can include a feed gas line 157 for delivery of water vapor (H₂O) to the plasma chamber 120 as part of the process gas. A control valve and/or mass flow controller 158 can be used to control the flow rate of the water vapor as part of the process gas into the plasma chamber 120. The water vapor can be used as a passivation agent for the silicon dioxide layers, silicon nitride layers, and other layers on the workpiece during a plasma strip process.

The water vapor can be introduced as a passivation agent in the apparatus 600 of FIG. 8 in other ways without deviating from the scope of the present disclosure. For instance, the water vapor can be introduced at a location in the processing chamber, such as at a location below the separation grid 200. As another example, the water vapor can be introduced between grid plates 210 and 220 of the separation grid.

In some embodiments, one or more of the plasma processing apparatus disclosed herein can include features to reduce water condensation along a delivery path for the water vapor. Example features can include, for instance, a heated mass flow controller and/or valve located downstream of a water vapor source in the water vapor feed line. Another example feature can include a heat trace operable to heat the water vapor feed line from the water vapor source to the chamber. The heat trace can be controlled to maintain the feed gas line temperature above that of the chamber and/or the water vapor source.

In some embodiments, the water vapor source can be located proximate to the chamber to reduce the feed gas line length and to reduce potential condensation area. In an example implementation, a the apparatus can be configured to introduce a dilution gas (e.g., N₂ or an inert gas, such as Ar, He, etc.) downstream of the water vapor feed line to reduce pressure of the water vapor inside the water vapor feed line and/or the chamber.

In some embodiments, the plasma processing apparatus can include a non-water cooled plasma chamber and/or non-water cooled processing chamber body to reduce condensation inside the plasma chamber and/or the processing chamber. Instead, a heat exchanger can be used in conjunction with a thermal fluid to circulate in channels of the chamber wall(s) to maintain an elevated chamber wall temperature to reduce condensation. In some embodiments, a pump used to evacuate the chamber(s) can be operated to reduce resident time of water vapor in the chamber(s).

Example process parameters for a plasma strip process using water vapor as a passivation agent will now be set forth.

### Example 1

Process Gas: H₂O (water vapor)+CF₄+O₂

Dilution Gas: N₂ and/or Ar and/or He

Process Pressure: about 300 mTorr to about 4000 mTorr

Inductively Coupled Plasma Source Power: about 600 W to about 5000 W

Workpiece Temperature: about 25° C. to about 400° C.

Process Period: about 30 seconds to about 1200 seconds

Gas Flow Rates for Process Gas:
H₂O (water vapor): about 400 sccm to about 1000 sccm
CF₄: about 150 sccm to about 500 sccm
O₂: about 300 sccm to about 750 sccm
Dilution Gas: about 0 sccm to about 1000 sccm

### Example 2

Process Gas: H₂O (water vapor)+CF₄+O₂+H₂

Dilution Gas: N₂ and/or Ar and/or He

Process Pressure: about 300 mTorr to about 4000 mTorr

Inductively Coupled Plasma Source Power: about 600 W to about 5000 W

Workpiece Temperature: about 25° C. to about 400° C.

Process Period: about 30 seconds to about 1200 seconds

Gas Flow Rates for Process Gas:
H₂O (water vapor): about 400 sccm to about 1000 sccm
CF₄: about 150 sccm to about 500 sccm
O₂: about 300 sccm to about 750 sccm
H₂: about 100 sccm to about 300 sccm
Dilution Gas: about 0 sccm to about 1000 sccm

### Example 3

Process Gas: H₂O (water vapor)+CF₄+O₂+N₂

Dilution Gas: N₂ and/or Ar and/or He

Process Pressure: about 300 mTorr to about 4000 mTorr

Inductively Coupled Plasma Source Power: about 600 W to about 5000 W

Workpiece Process Temperature: about 25° C. to about 400° C.

Process Period: about 30 seconds to about 1200 seconds

Gas Flow Rates for Process Gas:
H₂O (water vapor): about 400 sccm to about 1000 sccm
CF₄: about 150 sccm to about 500 sccm
O₂: about 300 sccm to about 750 sccm
N₂: about 400 sccm to about 1000 sccm
Dilution Gas: about 0 sccm to about 1000 sccm

### Example 4

Process Gas: H₂O (water vapor)+CH₂F₂+O₂+N₂

Dilution Gas: N₂ and/or Ar and/or He

Process Pressure: about 300 mTorr to about 4000 mTorr

Inductively Coupled Plasma Source Power: about 600 W to about 5000 W

Workpiece Process Temperature: about 25° C. to about 400° C.

Process Period: about 30 seconds to about 1200 seconds

Gas Flow Rates for Process Gas:
H₂O (water vapor): about 150 sccm to about 350 sccm
CH₂F₂: about 650 sccm to about 850 sccm
O₂: about 500 sccm to about 700 sccm
N₂: about 400 sccm to about 600 sccm
Dilution Gas: about 400 sccm to about 600 sccm

### Example 5

Process Gas: H₂O (water vapor)+CH₃F+O₂+N₂

Dilution Gas: N₂ and/or Ar and/or He

Process Pressure: about 300 mTorr to about 4000 mTorr

Inductively Coupled Plasma Source Power: about 600 W to about 5000 W

Workpiece Process Temperature: about 25° C. to about 400° C.

Process Period: about 30 seconds to about 1200 seconds

Gas Flow Rates for Process Gas:
H₂O (water vapor): about 150 sccm to about 350 sccm
CH₃F: about 650 sccm to about 850 sccm
O₂: about 1000 sccm to about 1400 sccm
N₂: about 400 sccm to about 600 sccm
Dilution Gas: about 400 sccm to about 600 sccm

Example selectivity for boron amorphous carbon hardmask layer (BACL) and ash rate results from a CF₄ containing process (Example 1) and a CH₂F₂ containing process are provided in Table 1 below:

TABLE 1

| | CF₄ Containing | CH₂F₂ Containing |
|---|---|---|
| Item | Process | Process |
| Ash Rate (Angstroms/Minute) | >2500 | >2500 |
| Selectivity: BACL/Oxide Layer | Infinite | Infinite |
| Selectivity: BACL/Nitride Layer | >5000 | Infinite |
| Selectivity: BACL/Polysilicon | >1000 | >250 |

Example aspects of the present disclosure can also be directed to processes for removing a titanium nitride (TiN) hardmask layer from a workpiece in semiconductor processing. Various materials such as TiN are widely used for dielectric etch as a hardmask to produce advanced semiconductor devices. Plasma strip processes can be used to remove TiN hardmask after dry etch processes. As device features continuously shrink, very high hardmask selectivities for TiN as compared to tungsten, oxide, and/or other nitride layers are required for effective post etch hardmask removal without causing damage to underlying structures.

Inadequate selectivity of the hardmask relative to tungsten and other underlying metal layers, oxide, or nitride layers in plasma strip processes can pose challenges in workpiece processing, such inadequate hardmask removal or damage to underlying substrate structures. For example, during hardmask removal, inadequate selectivities for the TiN hardmask can damage the underlying oxide, nitride, and tungsten layers causing increased resistance, which can lead to detrimental device performance. Conventional plasma stripping methods to remove hardmask layers can result in oxidation of tungsten layers or other metal layers along with oxide layer and nitride layer loss.

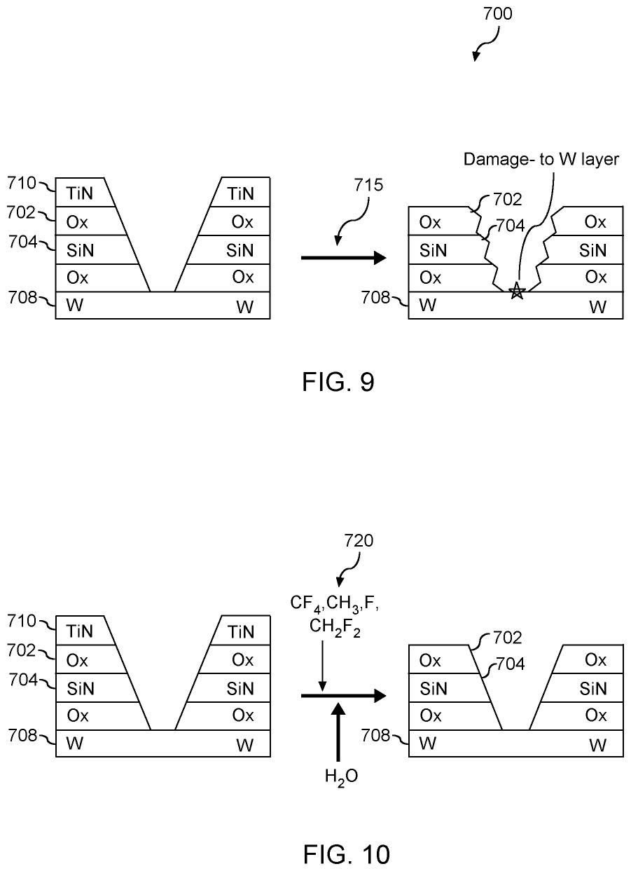

FIG. 9 depicts an example hardmask removal process for a high aspect ratio structure 700. The high aspect ratio structure 700 includes a plurality of oxide layers 702 and at least one silicon nitride layer 704 disposed on a substrate 708, such as a tungsten substrate. A hardmask 710 can remain on the high aspect ratio structure 700 after an etch process.

A plasma strip process 715 can be conducted on the high aspect ratio structure 700 to remove the hardmask 710. The plasma strip process can expose the hardmask 710 to one or more species generated in a plasma chamber to remove the hardmask 710. As shown in FIG. 9, if selectivity of the plasma strip process for the hardmask 710 is poor relative to the substrate 708, the plasma strip process 715 can result in damage to and/or removal of at least a portion of the substrate 708, negatively affecting the performance of the high aspect ratio structure 700. Additionally, the plasma strip process 715 can damage oxide layers 702 and silicon nitride layers 704, leading to oxide and nitride layer loss.

As shown in FIG. 10, a plasma strip process 720 according to example aspects of the present disclosure can be conducted on the high aspect ratio structure 700 to remove the hardmask 710. The plasma strip process 720 can expose the hardmask 710 to one or more species generated in a plasma chamber from a fluorine containing gas (e.g., CF₄, CH₂F₂, CH₃F) to remove the hardmask 710. The plasma strip process 720 can expose the workpiece to water vapor as a passivation agent to greatly improve selectivities for the hardmask 710 (e.g. the TiN hardmask layer) relative to the substrate layer 708 (e.g. the tungsten layer). Because of the improved selectivity of the plasma strip process 720, the high aspect ratio structure 700 can result in hardmask removal that does not oxidize, remove, or functionally damage the tungsten substrate, leading to improved function and performance of the fabricated device. Additionally, the plasma strip process 720 reduces damage and material loss to the oxide layers and the nitride layer, thus obtaining a smooth sidewall for the high aspect ratio structure 700.

FIGS. 3, 5, 6, 7, and 8 depict example plasma processing apparatus that can be used to perform the plasma strip process 720 according to example embodiments of the present disclosure. FIG. 4 depicts a flow diagram of one example method (300) of removing a titanium nitride hardmask according to example aspects of the present disclosure. The method (300) can be implemented in any suitable plasma processing apparatus to conduct the plasma strip process according to example embodiments of the present disclosure.

Example process parameters for a plasma strip process using water vapor to increase the selectivity to remove TiN hardmask layer were set forth in Examples 1-5.

Example selectivity for TiN hardmask layer removal from water vapor and fluorine containing plasma strip processes are provided in Table 2 below:

TABLE 2

| | ALD TiN | ALD TiN | |
|---|---|---|---|
| | Pre-plasma | Post-plasma | |
| Run | strip process | strip process | |
| Number | with H₂O | with H₂O | Delta |
| 1 | 122.39 | 1.08 | 121.31 |
| 2 | 122.1 | 1.12 | 120.98 |
| 3 | 122.47 | 1.09 | 121.38 |
| 4 | 122.47 | 7.1 | 115.37 |
| 5 | 122.64 | 1.13 | 121.51 |

| | |
|---|---|
| Average | 120.11 |
| SD | 2.376443 |

Example selectivity for the tungsten substrate layer from exposure to a water vapor and fluorine containing plasma strip process are provided in Table 3 below:

TABLE 3

| Film | Pre-RS (ohm) | Pos-RS (ohm) | % Delta |
|---|---|---|---|
| ALD W | 3.34097 | 3.340753 | −0.0065 |
| PVD W | 1.04314 | 1.04399 | 0.081418 |

As shown in Tables 2 and 3, the plasma strip process according to the example embodiments of the present disclosure can achieve selectivities for TiN well above 100. With such selectivities for TiN, tungsten oxidation can be controlled, and the oxide and silicon nitride layers can maintain a smooth sidewall configuration.

While the present subject matter has been described in detail with respect to specific example embodiments thereof, it will be appreciated that those skilled in the art, upon attaining an understanding of the foregoing may readily produce alterations to, variations of, and equivalents to such embodiments. Accordingly, the scope of the present disclosure is by way of example rather than by way of limitation, and the subject disclosure does not preclude inclusion of such modifications, variations and/or additions to the present subject matter as would be readily apparent to one of ordinary skill in the art.

What is claimed is:

1. A method for processing a workpiece, the method comprising:
supporting a workpiece on a workpiece support in a processing chamber, the workpiece comprising a hardmask layer;
generating a plasma from a process gas in a plasma chamber using a plasma source, the process gas comprising a fluorine containing gas;
exposing the workpiece to one or more radicals generated in the plasma to perform a plasma strip process on the workpiece to at least partially remove the hardmask layer from the workpiece; and
exposing the workpiece to water vapor as a passivation agent during the plasma strip process.

2. The method of claim 1, wherein the workpiece comprises one or more silicon dioxide layers and one or more silicon nitride layers.

3. The method of claim 1, wherein the plasma chamber is separated from the processing chamber by a separation grid.

4. The method of claim 1, wherein exposing the workpiece to water vapor as a passivation agent comprises introducing water vapor into the plasma chamber as part of the process gas.

5. The method of claim 1, wherein the fluorine containing gas comprises CF₄.

6. The method of claim 1, wherein the fluorine containing gas comprises CH₂F₂.

7. The method of claim 1, wherein the fluorine containing gas comprises CH₃F.

8. The method of claim 1, wherein the process gas comprises an oxygen gas.

9. The method of claim 1, wherein the process gas comprises a nitrogen gas.

10. The method of claim 1, wherein the process gas comprises a hydrogen gas.

11. The method of claim 1, wherein the hardmask is a boron doped amorphous hardmask.

12. The method of claim 1, wherein the hardmask is a titanium nitride hardmask.

13. The method of claim 1, wherein the workpiece comprises a substrate layer.

14. The method of claim 13, wherein the substrate layer comprises tungsten.

15. The method of claim 1, wherein the plasma strip process is implemented for a process period, the process period being in a range of about 30 seconds to about 1200 seconds.

16. The method of claim 1, wherein the plasma strip process is conducted at a process pressure in the processing chamber, the process pressure being in the range of about 300 mT to about 4000 mT.

17. The method of claim 1, wherein the plasma strip is conducted at a source power for an inductively coupled plasma source, the source power being in the range of about 600W to about 5000W.

18. The method of claim 1, wherein the plasma strip process is conducted with the workpiece at a process temperature, the process temperature being in a range of about 25° C. to about 400° C.

19. The method of claim 1, wherein exposing the workpiece to water vapor as a passivation agent comprises introducing water vapor into the processing chamber.

20. The method of claim 3, wherein exposing the workpiece to water vapor as a passivation agent comprises introducing water vapor into the processing chamber at a location beneath the separation grid.

21. The method of claim 3, wherein exposing the workpiece to water vapor as a passivation agent comprises introducing water vapor into the processing chamber at a location between a first grid plate and a second grid plate of the separation grid.

22. The method of claim 1, wherein an ash rate of the plasma strip process is about 1500 Angstroms/minute or more.

23. A plasma processing apparatus, comprising:
a processing chamber having a workpiece support, the workpiece support configured to support a workpiece during plasma processing;
a plasma chamber separated from the processing chamber by a separation grid;
an inductively coupled plasma source configured to induce a plasma in a process gas in the plasma chamber; wherein radicals generated in the plasma pass through the separation grid for exposure to the workpiece during plasma processing;
a water vapor feed line operable to deliver water vapor to one or more of the plasma chamber, the separation grid, and the processing chamber;
wherein the water vapor feed line comprises a temperature regulation system configured to reduce condensation along a delivery path of water vapor from the water vapor feed line.

24. The plasma processing apparatus of claim 23, wherein the temperature regulation system comprises a heat source.
